(19) United States
(12) Patent Application Publication
(10) Pub. No.: US 2026/0068400 A1
(43) Pub. Date: Mar. 5, 2026

(54) DISPLAY DEVICE AND ELECTRONIC DEVICE INCLUDING THE SAME

(71) Applicant: Samsung Display Co., LTD., Yongin-si (KR)

(72) Inventors: Kyung Hee LEE, Yongin-si (KR); Tae Min KIM, Yongin-si (KR); Dong Geun SHIN, Yongin-si (KR); Seung Hee LEE, Yongin-si (KR)

(21) Appl. No.: 19/171,772

(22) Filed: Apr. 7, 2025

(30) Foreign Application Priority Data
Sep. 5, 2024 (KR) 10-2024-0120931

(51) Int. Cl. H10H 29/854; H10H 29/85; H10K 59/38; H10K 59/40; H10K 59/80

(52) U.S. Cl. CPC H10H 29/854; H10H 29/8517; H10K 59/38; H10K 59/40; H10K 59/8731

(57) ABSTRACT

A display device and an electronic device including the same are provided. The display device includes a substrate, a light-emitting element layer disposed on the substrate and emitting light, an encapsulation layer disposed on the light-emitting element layer, a touch sensing layer disposed on the encapsulation layer, a color filter layer disposed on the touch sensing layer, and an overcoat layer disposed on the color filter layer, wherein the overcoat layer includes organic films and inorganic films alternately stacked on one another, and wherein the organic films are disposed at a bottom and a top of the overcoat layer, respectively.

This application claims priority to Korean Patent Application No. 10-2024-0120931, filed on Sep. 5, 2024, and all the benefits accruing therefrom under 35 U.S.C. § 119, the content of which in its entirety is herein incorporated by reference.

### BACKGROUND

### 1. Field

The disclosure relates to a display device and an electronic device including the same.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices include an organic light-emitting display device including organic light-emitting elements, an inorganic light-emitting display device including inorganic light-emitting elements such as inorganic semiconductor, and a micro light-emitting display device including micro light-emitting elements.

An organic light-emitting element may include two opposing electrodes and an emissive layer interposed therebetween. Electrons and holes supplied from the two electrodes are recombined in the emissive layer to generate excitons, and the generated excitons relax from the excited state to the ground state so that light may be emitted.

A separate light source such as a backlight unit is not desired in an organic light-emitting display device including organic light-emitting elements, and thus the organic light-emitting display device consumes less power and may be made relatively light and thin, as well as exhibiting high-quality characteristics such as relatively wide viewing angle, relatively high luminance and contrast, and relatively fast response speed. Accordingly, an organic light-emitting display device is attracting attention as the next generation display device.

### SUMMARY

Features of the disclosure provide a display device capable of addressing color filter defects due to moisture, and an electronic device including the same.

It should be noted that features of the disclosure are not limited to the above-mentioned feature; and other features of the disclosure will be apparent to those skilled in the art from the following descriptions.

In an embodiment of the disclosure, a display device includes a substrate, a light-emitting element layer disposed on the substrate and emitting light, an encapsulation layer disposed on the light-emitting element layer, a touch sensing layer disposed on the encapsulation layer, a color filter layer disposed on the touch sensing layer, and an overcoat layer disposed on the color filter layer. The overcoat layer includes organic films and inorganic films alternately stacked on one another, and the organic films are disposed at a bottom and a top of the overcoat layer, respectively.

In an embodiment, the organic film disposed at the bottom of the overcoat layer among the organic films contacts the color filter layer.

In an embodiment, the color filter layer may include at least one color filter and at least one color pattern. A degree of planarization (“DOP”) of the organic film disposed at the bottom of the overcoat layer among the organic films is 90% or higher.

In an embodiment, the organic film disposed at the top of the overcoat layer includes a different material from a material of remaining (the other) organic films.

In an embodiment, the organic film disposed at the top of the overcoat layer among the organic films includes a wear-resistant material, and the remaining (the other) organic films among the organic films do not include the wear-resistant material.

In an embodiment, the wear-resistant material includes at least one selected from silicone, polytetrafluoroethylene (“PTFE”), calcium carbonate, maleic acid, molybdenum, and magnesium stearate.

In an embodiment, each of the inorganic films is disposed between the organic films, and includes one of silicon nitride (SiNx), silicon oxide (SiOx), and silicon oxynitride (SiON).

In an embodiment, each of the inorganic films has a thickness of 10% or less of a thickness of one of the organic films.

In an embodiment, each of the organic films has a thickness of 1 micrometer (μm) to 20 μm.

In an embodiment, a difference between a refractive index of the organic films and a refractive index of the inorganic films is equal to or less than 0.05.

In an embodiment, the organic films include polysilsesquioxane.

In an embodiment of the disclosure, a display device includes a substrate, a light-emitting element layer disposed on the substrate and emitting light, an encapsulation layer disposed on the light-emitting element layer, a touch sensing layer disposed on the encapsulation layer, a color filter layer disposed on the touch sensing layer, and an overcoat layer disposed on the color filter layer. The overcoat layer includes organic films and inorganic films alternately stacked on one another, and a number of the organic films is greater than a number of the inorganic films.

In an embodiment, the organic film disposed at the top of the overcoat layer includes a different material from a material of remaining (the other) organic films.

In an embodiment, the organic film disposed at the top of the overcoat layer among the organic films includes a wear-resistant material, and the remaining (the other) organic films among the organic films do not include the wear-resistant material.

In an embodiment, the wear-resistant material includes at least one selected from silicone, PTFE, calcium carbonate, maleic acid, molybdenum, and magnesium stearate.

In an embodiment, each of the inorganic films is disposed between the organic films, and includes one of silicon nitride (SiNx), silicon oxide (SiOx), and silicon oxynitride (SiON).

In an embodiment, each of the inorganic films has a thickness of 10% or less of a thickness of one of the organic films.

In an embodiment, each of the organic films has a thickness of 1 μm to 20 μm.

In an embodiment, a difference between a refractive index of the organic films and a refractive index of the inorganic films is equal to or less than 0.05.

In an embodiment of the disclosure, an electronic device, includes a display device configured to provide an image, a processor configured to provide an image data signal to the display device, a memory configured to store a data information for operation, and a power module configured to generate power. The display device includes, a substrate, a light-emitting element layer disposed on the substrate and emitting light, an encapsulation layer disposed on the light-emitting element layer, a touch sensing layer disposed on the encapsulation layer, a color filter layer disposed on the touch sensing layer, and an overcoat layer disposed on the color filter layer, the overcoat layer includes organic films and inorganic films alternately stacked on one another, and the organic films are disposed at a bottom and a top of the overcoat layer, respectively.

In an embodiment of the disclosure, it is possible to suppress bubble defects and film delamination in a display device by preventing external moisture from permeating into a color filter layer by including an overcoat layer in which organic films and inorganic films are alternately arranged.

In an embodiment of the disclosure, it is possible to improve wear resistance by disposing an organic film with wear-resistant properties at the top of an overcoat layer in a display device.

It should be noted that effects of the disclosure are not limited to those described above and other effects of the disclosure will be apparent to those skilled in the art from the following descriptions.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view of an embodiment of an electronic device according to the disclosure.

FIG. 2 is a perspective view showing an embodiment of a foldable display device in an embodiment of the disclosure when it is folded.

FIG. 3 is a perspective view showing the foldable display device of FIG. 2 when it is unfolded.

FIG. 4 is a perspective view showing an embodiment of a display device included in an electronic device according to the disclosure.

FIG. 5 is a cross-sectional view of the display device of FIG. 4 seen from the side.

FIG. 6 is a plan view showing an embodiment of a display layer of a display device according to the disclosure.

FIG. 7 is a plan view showing an embodiment of a touch sensing layer of a display device according to the disclosure.

FIG. 8 is a plan view showing an embodiment of emission areas of a display device according to the disclosure.

FIG. 9 is a cross-sectional view taken along line X-X′ of FIG. 8.

FIG. 10 is an enlarged cross-sectional view of an embodiment of an overcoat layer of a display device according to the disclosure.

FIG. 11 is a view schematically showing a path of moisture permeation in a single overcoat layer.

FIG. 12 is a view schematically showing an embodiment of a path of moisture permeation in an overcoat layer according to the disclosure.

FIG. 13 is an image of the display panel according to Comparative Example after the reliability evaluation.

FIG. 14 is an image of an embodiment of the display panel after the reliability evaluation.

FIG. 15 is an image of the display panel according to Comparative Example after the wear resistance evaluation.

FIG. 16 is an image of an embodiment of the display panel after the wear resistance test.

FIG. 17 is a block diagram of an embodiment of an electronic device according to the disclosure.

FIG. 18 is a schematic diagram of an electronic device according to various embodiments of the disclosure.

### DETAILED DESCRIPTION

The disclosure will now be described more fully hereinafter with reference to the accompanying drawings, in which preferred embodiments of the disclosure are shown. This disclosure may, however, be embodied in different forms and should not be construed as limited to the embodiments set forth herein. Rather, these embodiments are provided so that this disclosure will be thorough and complete, and will filly convey the scope of the disclosure to those skilled in the art.

It will also be understood that when a layer is referred to as being “on” another layer or substrate, it may be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” may therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” may, therefore, encompass both an orientation of above and below.

The terms such as “module” as used herein are intended to mean a hardware component such as a circuitry that performs a predetermined function. The hardware component may include a field-programmable gate array (“FPGA”) or an application-specific integrated circuit (“ASIC”), for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Each of the features of the various embodiments of the disclosure may be combined or combined with each other, in part or in whole, and technically various interlocking and driving are possible. Each embodiment may be implemented independently of each other or may be implemented together in an association.

Hereinafter, embodiments of the disclosure will be described with reference to the accompanying drawings.

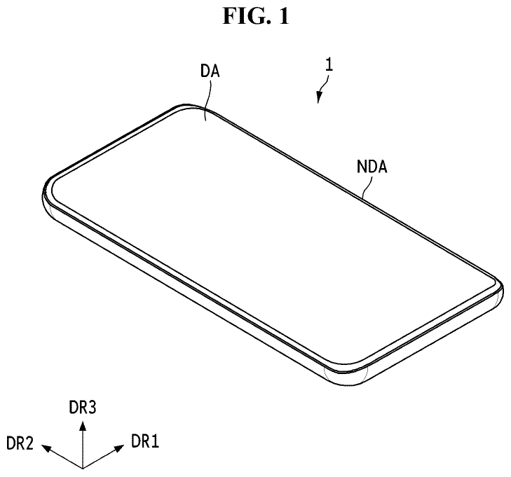

FIG. 1 is a perspective view of an embodiment of an electronic device according to the disclosure.

Referring to FIG. 1, an electronic device 1 displays a moving image or a still image. The electronic device 1 may refer to any electronic device that provides a display screen. In an embodiment, the electronic device 1 may include a television set, a laptop computer, a monitor, an electronic billboard, the Internet of Things devices, a mobile phone, a smart phone, a tablet personal computer (“PC”), an electronic watch, a smart watch, a watch phone, a head-mounted display device, a mobile communications terminal, an electronic notebook, an electronic book, a portable multimedia player (“PMP”), a navigation device, a game console and a digital camera, a camcorder, etc., for example.

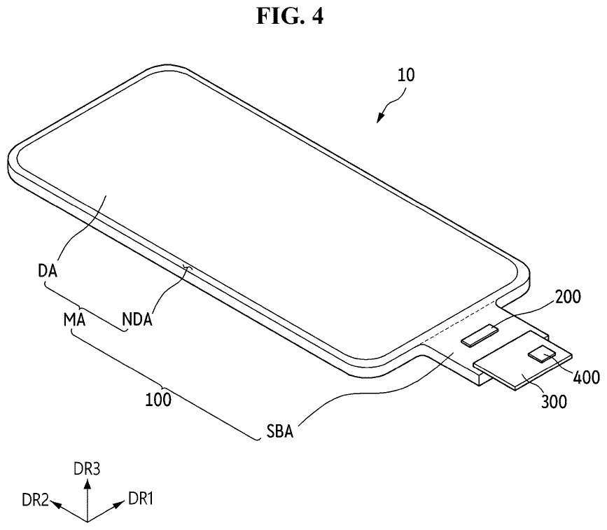

The electronic device 1 may include a display device 10 (refer to FIG. 4) for providing a display screen. In embodiments, the display device may include an inorganic light-emitting diode display device, an organic light-emitting display device, a quantum-dot light-emitting display device, a plasma display device, a field emission display device, etc. In the following description, an organic light-emitting diode display device is employed in an embodiment of the display device, but the disclosure is not limited thereto. Any other display device may be employed as long as the technical idea of the disclosure may be equally applied.

The shape of the electronic device 1 may be modified in a variety of ways. In an embodiment, the electronic device 1 may have shapes such as a rectangle with longer lateral sides, a rectangle with longer vertical sides, a square, a quadrangle with rounded corners (vertices), other polygons, a circle, etc., for example. The shape of a display area DA of the electronic device 1 may also be similar to the overall shape of the electronic device 1. In the example shown in FIG. 1, the electronic device 1 has a quadrangular shape, e.g., rectangular shape with the longer sides in a second direction DR2.

The electronic device 1 may include the display area DA and a non-display area NDA. In the display area DP, images may be displayed. In the non-display area NDA, images are not displayed. The display area DP may be also referred to as an active area, while the non-display area NDA may also be also referred to as an inactive area. The display area DA may generally occupy the center of the electronic device 1.

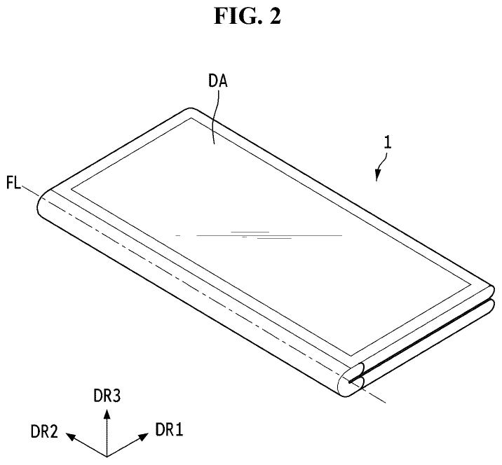

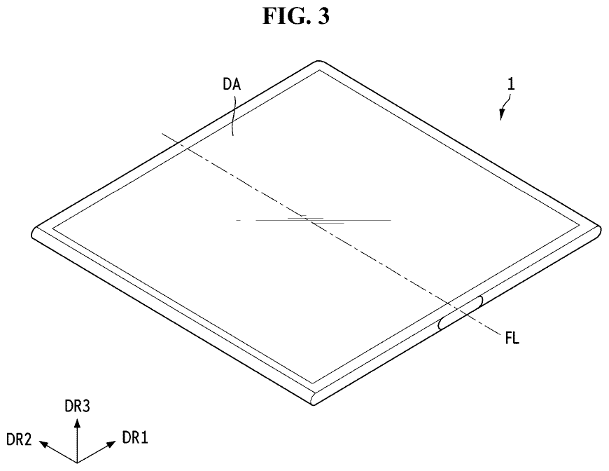

FIG. 2 is a perspective view showing an embodiment of a foldable display device in an embodiment of the disclosure when it is folded. FIG. 3 is a perspective view showing the foldable display device of FIG. 2 when it is unfolded.

Referring to FIGS. 2 and 3, an electronic device 1 in the embodiment may be a foldable display device. The foldable electronic device 1 may be folded along a folding axis FL. The display area DA may be disposed on the outside and/or inside of the foldable electronic device 1. According to the embodiment of FIGS. 2 and 3, the display area DA is disposed on each of the outside and inside of the foldable electronic device 1.

The display area DA may be disposed on the outer side of electronic device 1. The outer surface of the electronic device 1 when it is folded may include the display area DA, and the inner surface of the electronic device 1 when it is unfolded may include the display area DA.

FIG. 4 is a perspective view showing an embodiment of a display device included in an electronic device according to the disclosure.

Referring to FIG. 4, the electronic device 1 in the embodiment of the disclosure may include a display device 10. The display device 10 may provide a display screen where images are displayed in the electronic device 1. The display device 10 may have a shape similar to that of the electronic device 1 when viewed from the top. In an embodiment, the display device 10 may have a shape similar to a rectangle having shorter sides in the first direction DR1 and longer sides in the second direction DR2, for example. The corners where the shorter sides in the first direction DR1 meet the longer sides in the second direction DR2 may be rounded with a predetermined curvature. It should be understood, however, that the disclosure is not limited thereto. The corners may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include the display area DA including pixels for displaying images, and the non-display area NDA disposed around the display area DA. The display area DA may output lights from a plurality of emission areas or a plurality of open areas. In an embodiment, the display panel 100 may include a pixel circuit including switching elements, a pixel-defining layer that defines the emission areas or the open areas, and self-light-emitting elements, for example.

In an embodiment, the self-light-emitting element may include, but is not limited to, at least one of: an organic light-emitting diode including an organic emissive layer, a quantum-dot light-emitting diode (“quantum LED”) including a quantum-dot emissive layer, an inorganic light-emitting diode (“inorganic LED”) including an inorganic semiconductor, and a micro light-emitting diode (“micro LED”), for example.

The non-display area NDA may be disposed on the outer side of the display area DA. The non-display area NDA may be defined as the edge of the main area MA of the display panel 100. The non-display area NDA may include a gate driver (not shown) that applies gate signals to gate lines, and fan-out lines (not shown) that connect the display driver 200 with the display area DA.

The subsidiary area SBA may be extended from one side of the main area MA. The subsidiary area SBA may include a flexible material that may be bent, folded, or rolled. In an embodiment, when the subsidiary area SBA is bent, the subsidiary area SBA may overlap the main area MA in the thickness direction (third direction DR3), for example. The subsidiary area SBA may include pads connected to the display driver 200 and the circuit board 300. In another embodiment, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (“IC”) and may be attached on the display panel 100 by a chip-on-glass (“COG”) technique, a chip-on-plastic (“COP”) technique, or ultrasonic bonding. In an embodiment, the display driver 200 may be disposed in the subsidiary area SBA and may overlap with the main area MA in the thickness direction as the subsidiary area SBA is bent, for example. In another embodiment, the display driver 200 may be disposed (e.g., mounted) on the circuit board 300.

The circuit board 300 may be attached on the pad area of the display panel 100 using an anisotropic conductive film (“ACF”). Lead lines of the circuit board 300 may be electrically connected to the pads of the display panel 100. The circuit board 300 may be a flexible printed circuit board (“FPCB”), a printed circuit board (“PCB”), or a flexible film such as a chip-on-film (“COF”).

The touch driver 400 may be disposed (e.g., mounted) on the circuit board 300. The touch driver 400 may be connected to a touch sensing unit of the display panel 100. The touch driver 400 may supply a touch driving signal to a plurality of touch electrodes of the touch sensing unit and may sense a change in the capacitance between the plurality of touch electrodes. In an embodiment, the touch driving signals may be pulse signals having a predetermined frequency, for example. The touch driver 400 may determine whether there is an input and may find the coordinates of the input based on the amount of the change in the capacitance between the touch electrodes. The touch driver 400 may be implemented as an integrated circuit (“IC”).

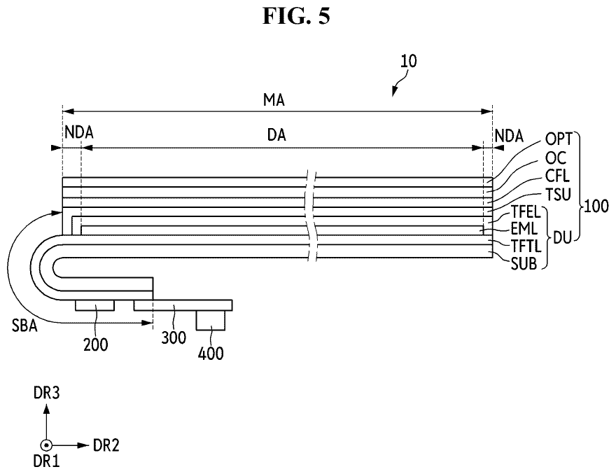

FIG. 5 is a cross-sectional view of the display device of FIG. 4 seen from the side.

Referring to FIG. 5, the display panel 100 may include a display layer DU, a touch sensing layer TSU, a color filter layer CFL, an overcoat layer OC, and an optical layer OPT. The display layer DU may include a substrate SUB, a thin-film transistor layer TFTL, a light-emitting element layer EML and an encapsulation layer TFEL.

The substrate SUB may be a base substrate or a base member. The substrate SUB may be a flexible substrate that may be bent, folded, or rolled. In an embodiment, the substrate SUB may include, but is not limited to, a polymer resin such as polyimide (“PI”), for example. In another embodiment, the substrate SUB may include a glass material or a metal material.

The thin-film transistor layer TFTL may be disposed on the substrate SUB. The thin-film transistor layer TFTL may include a plurality of thin-film transistors forming pixel circuits of pixels. The thin-film transistor layer TFTL may include gate lines, data lines, voltage lines, gate control lines, fan-out lines for connecting the display driver 200 with the data lines, lead lines for connecting the display driver 200 with the pads, etc. Each of the thin-film transistors may include a semiconductor region, a source electrode, a drain electrode, and a gate electrode. In an embodiment, when the gate driver is formed on one side of the non-display area NDA of the display panel 100, the gate driver may include thin-film transistors, for example.

The thin-film transistor layer TFTL may be disposed in the display area DA, the non-display area NDA and the subsidiary area SBA. The thin-film transistors in each of the pixels, the gate lines, the data lines and the voltage lines in the thin-film transistor layer TFTL may be disposed in the display area DA. The gate control lines and the fan-out lines in the thin-film transistor layer TFTL may be disposed in the non-display area NDA. The lead lines of the thin-film transistor layer TFTL may be disposed in the subsidiary area SBA.

The light-emitting element layer EML may be disposed on the thin-film transistor layer TFTL. The light-emitting element layer EML may include a plurality of light-emitting elements each including a pixel electrode, a common electrode and an emissive layer to emit light, and a pixel-defining film for defining the pixels. The plurality of light-emitting elements in the light-emitting element layer EML may be disposed in the display area DA.

In an embodiment of the disclosure, the emissive layer may be an organic emissive layer including an organic material. The emissive layer may include a hole transporting layer, an organic light-emitting layer and an electron transporting layer. When the pixel electrode receives a voltage and the common electrode receives a cathode voltage through the thin-film transistors in the thin-film transistor layer TFTL, the holes and electrons may move to the organic light-emitting layer through the hole transporting layer and the electron transporting layer, respectively, such that they combine in the organic light-emitting layer to emit light.

In another embodiment, the light-emitting elements may include quantum-dot light-emitting diodes each including a quantum-dot emissive layer, inorganic light-emitting diodes each including an inorganic semiconductor, or micro light-emitting diodes.

An encapsulation layer TFEL may cover the upper and side surfaces of the light-emitting element layer EML, and may protect the light-emitting element layer EML. The encapsulation layer TFEL may include at least one inorganic film and at least one organic film for encapsulating the light-emitting element layer EML.

The touch sensing layer TSU may be disposed on the encapsulation layer TFEL. The touch sensing layer TSU may include a plurality of touch electrodes for sensing a user's touch by capacitive sensing, and touch lines connecting the plurality of touch electrodes with the touch driver 400. In an embodiment, the touch sensing layer TSU may sense a user's touch by mutual capacitance sensing or self-capacitance sensing, for example.

The plurality of touch electrodes of the touch sensing layer TSU may be disposed in a touch sensor area overlapping the display area DA. The touch lines of the touch sensing layer TSU may be disposed in a touch peripheral area overlapping the non-display area NDA.

The color filter layer CFL may be disposed on the touch sensing layer TSU. The color filter layer CFL may include a plurality of color filters associated with the plurality of emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL may prevent distortion of colors due to the reflection of external light.

Since the color filter layer CFL is disposed directly on the touch sensing layer TSU, the display device 10 may desire no separate substrate for the color filter layer CFL. Therefore, the thickness of the display device 10 may be relatively small.

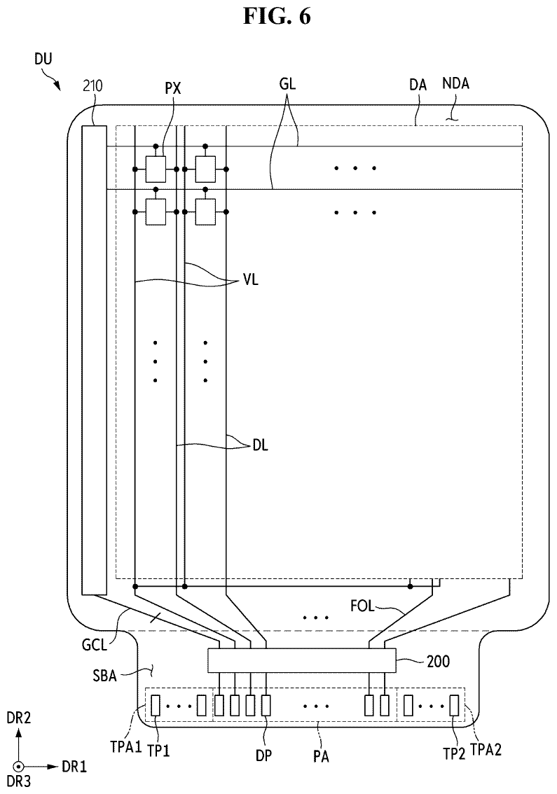

FIG. 6 is a plan view showing an embodiment of a display layer of a display device according to the disclosure.

Referring to FIG. 6, the display layer DU may include a display area DA and a non-display area NDA.

The display area DA may be disposed at the center of display device 100. In the display area DA, a plurality of pixels PX, a plurality of gate lines GL, a plurality of data lines DL and a plurality of voltage lines may be disposed. Each of the plurality of pixels PX may be defined as the minimum unit that outputs light.

The plurality of gate lines GL may supply the gate signals received from the gate driver 210 to the plurality of pixels PX. The plurality of gate lines GL may be extended in the first direction DR1 and may be spaced apart from one another in the second direction DR2 intersecting the first direction DR1.

The plurality of data lines DL may supply the data voltages received from the display driver 200 to the plurality of pixels PX. The plurality of data lines DL may be extended in the second direction DR2 and may be spaced apart from one another in the first direction DR1.

The plurality of voltage lines VL may apply the supply voltage received from the display driver 200 to the plurality of pixels PX. The supply voltage may be at least one of a driving voltage, an initialization voltage, a reference voltage and a low-level voltage. The plurality of voltage lines VL may be extended in the second direction DR2 and may be spaced apart from one another in the first direction DR1.

The non-display area NDA may surround the display area DA. In the non-display area NDA, the gate driver 210, fan-out lines FOL, and gate control lines GCL may be disposed. The gate driver 210 may generate a plurality of gate signals based on the gate control signal, and may sequentially supply the plurality of gate signals to the plurality of gate lines GL in a predetermined order.

The fan-out lines FOL may be extended from the display driver 200 to the display area DA. The fan-out lines FOL may supply the data voltage received from the display driver 200 to the plurality of data lines DL.

A gate control line GCL may be extended from the display driver 200 to the gate driver 210. The gate control line GCL may supply the gate control signal received from the display driver 200 to the gate driver 210.

The subsidiary area SBA may include the display driver 200, a pad area PA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, so that the luminance of the plurality of pixels PX may be controlled. The display driver 200 may supply a gate control signal to the gate driver 210 through the gate control lines GCL.

The pad area PA, the first touch pad area TPA1 and the second touch pad area TPA2 may be disposed at the edge of the subsidiary area SBA. The pad area PA, the first touch pad area TPA1 and the second touch pad area TPA2 may be electrically connected to the circuit board 300 using a material such as an anisotropic conductive film and a self assembly anisotropic conductive paste (“SAP”). The first touch pad area TPA1 may include first touch pads TP1, the second touch pad area TPA2 may include second touch pads TP2, and they may be electrically connected to the circuit board 300.

The pad area PA may include a plurality of display pads DP. The plurality of display pads DP may be connected to a graphic system through the circuit board 300. The plurality of display pads DP may be connected to the circuit board 300 to receive digital video data and may supply the digital video data to the display driver 200.

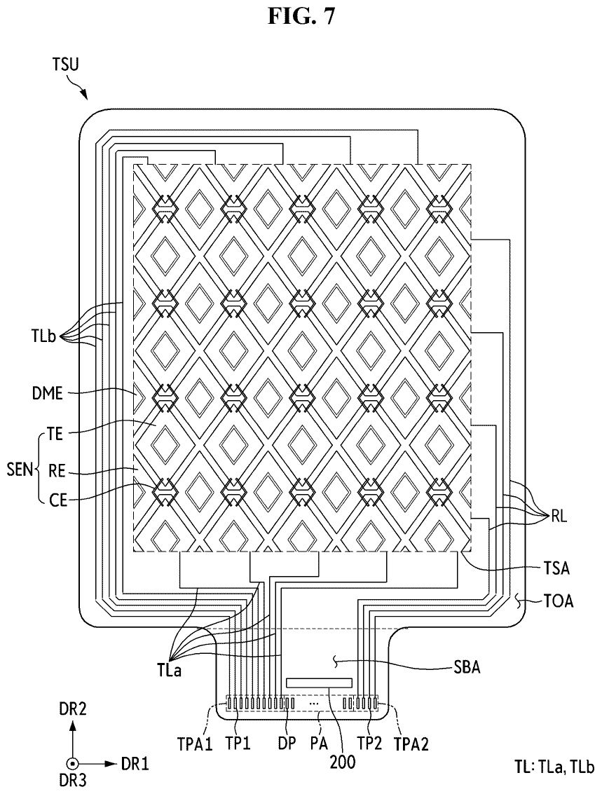

FIG. 7 is a plan view showing an embodiment of a touch sensing layer of a display device according to the disclosure.

Referring to FIG. 7, the touch sensing layer TSU may include a touch sensor area TSA that senses a user's touch, and a touch peripheral area TOA disposed around the touch sensor area TSA. The touch sensor area TSA may be disposed in the display area DA of the display device 10, and the touch peripheral area TOA may be disposed in the non-display area NDA of the display device 10.

The touch sensor area TSA may include a plurality of touch electrodes SEN and a plurality of dummy electrodes DME. The plurality of touch electrodes SEN may form mutual capacitance or self capacitance to sense a touch of an object or person. The plurality of touch electrodes SEN may include a plurality of driving electrodes TE, a plurality of sensing electrodes RE, and bridge electrodes CE.

The driving electrodes TE may be arranged in the first direction DR1 and in the second direction DR2. The driving electrodes TE may be spaced apart from one another in the first direction DR1 and in the second direction DR2. The driving electrodes TE next (adjacent) to one another in the second direction DR2 may be electrically connected through bridge electrodes CE.

The plurality of driving electrodes TE may be connected to the first touch pads TP1 through driving lines TL. The driving lines TL may include lower driving lines TLa and upper driving lines TLb. In an embodiment, the driving electrodes TE disposed on the lower side of the touch sensor area TSA may be connected to the first touch pads TP1 through the lower driving lines TLa, and the driving electrodes TE disposed on the upper side of the touch sensor area TSA may be connected to the first touch pads TP1 through the upper driving lines TLb, for example. The lower driving lines TLa may be extended to the first touch pads TP1 beyond the lower side of the touch peripheral area TOA. The upper driving lines TLb may be extended to the first touch pads TP1 via the upper side, the left side and the lower side of the touch peripheral area TOA. The first touch pads TP1 may be connected to the touch driver 400 through the circuit board 300.

The bridge electrodes CE may be bent at least once. Although the bridge electrodes CE may have the shape of angle brackets “<” or “>”, the shape of the bridge electrodes CE when viewed from the top is not limited thereto. The driving electrodes TE next (adjacent) to one another in the second direction DR2 may be connected by the plurality of bridge electrodes CE. Even when one of the bridge electrodes CE is disconnected, the driving electrodes TE may be stably connected through the remaining bridge electrodes CE. The driving electrodes TE next (adjacent) to each other may be connected by two bridge electrodes CE, but the number of bridge electrodes CE is not limited thereto.

The bridge electrodes CE may be disposed in a different layer from the plurality of driving electrodes TE and the plurality of sensing electrodes RE. The sensing electrodes RE next (adjacent) to one another in the first direction DR1 may be electrically connected through connectors disposed in the same layer as the plurality of driving electrodes TE or the plurality of sensing electrodes RE. The driving electrodes TE next (adjacent) to one another in the second direction DR2 may be electrically connected through the bridge electrodes CE disposed in a different layer from the plurality of driving electrodes TE or the plurality of sensing electrodes RE. Accordingly, even though the bridge electrodes CE overlap with the plurality of sensing electrodes RE in the z-axis direction, the plurality of driving electrodes TE and the plurality of sensing electrodes RE may be insulated from each other. Mutual capacitance may be formed between the driving electrodes TE and the sensing electrodes RE.

The sensing electrodes RE may be extended in the first direction DR1 and may be spaced apart from one another in the second direction DR2. The sensing electrodes RE may be arranged in the first direction DR1 and the second direction DR2, and the sensing electrodes RE next (adjacent) to one another in the first direction DR1 may be electrically connected through connectors.

The plurality of sensing electrodes RE may be connected to second touch pads TP2 through sensing lines RL. In an embodiment, the sensing electrodes RE disposed on the right side of the touch sensor area TSA may be connected to the second touch pads TP2 through the sensing lines RL, for example. The sensing lines RL may be extended to the second touch pads TP2 along the right side and the lower side of the touch peripheral area TOA. The second touch pads TP2 may be connected to the touch driver 400 through the circuit board 300.

Each of the plurality of dummy electrodes DME may be surrounded by the driving electrode TE or the sensing electrode RE. Each of the plurality of dummy electrodes DME may be spaced apart from and insulated from the driving electrode TE or the sensing electrode RE. Accordingly, the dummy electrodes DME may be electrically floating.

The pad area PA, the first touch pad area TPA1 and the second touch pad area TPA2 may be disposed at the edge of the subsidiary area SBA. The pad area PA, the first touch pad area TPA1 and the second touch pad area TPA2 may be electrically connected to the circuit board 300 using a low-resistance, high-reliability material such as an anisotropic conductive film and an SAP.

The first touch pad area TPA1 may be disposed on one side of the pad area PA and may include a plurality of first touch pads TP1. The plurality of first touch pads TP1 may be electrically connected to the touch driver 400 disposed on the circuit board 300. The plurality of first touch pads TP1 may supply touch driving signals to the plurality of driving electrodes TE through the plurality of driving lines TL.

The second touch pad area TPA2 may be disposed on the opposite side of the pad area PA and may include a plurality of second touch pads TP2. The plurality of second touch pads TP2 may be electrically connected to the touch driver 400 disposed on the circuit board 300. The touch driver 400 may receive a touch sensing signal through the plurality of sensing lines RL connected to the plurality of second touch pads TP2, and may sense a change in the capacitance between the driving electrodes TE and the sensing electrodes RE.

In another embodiment, the touch driver 400 may supply a touch driving signal to each of the plurality of driving electrodes TE and the plurality of sensing electrodes RE, and may receive a touch sensing signal from each of the plurality of driving electrodes TE and the plurality of sensing electrodes RE. The touch driver 400 may sense a change in the amount of charges in each of the plurality of driving electrodes TE and the plurality of sensing electrodes RE based on the touch sensing signal.

Although the structure of the plurality of touch electrodes SEN of the touch sensing layer TSU has the diamond shape and connected in the first and second directions DR1 and DR2 in the example shown in FIG. 7, the structure is not limited thereto. The plurality of touch electrodes SEN may be formed in a mesh topology.

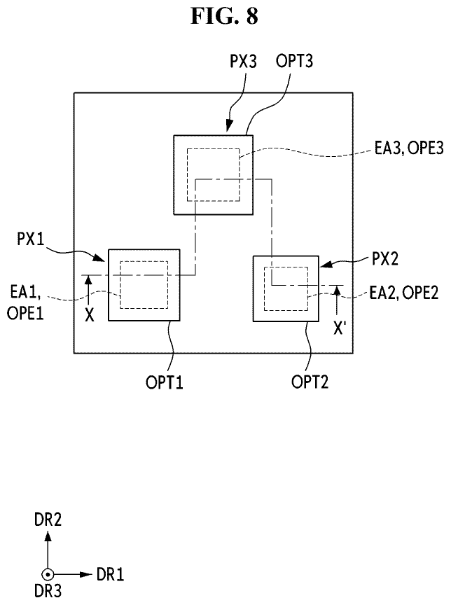

FIG. 8 is a plan view showing an embodiment of emission areas of a display device according to the disclosure.

Referring to FIG. 8, a display device 10 may include a plurality of pixels PX1, PX2 and PX3 arranged in a display area DA. The plurality of pixels PX1, PX2 and PX3 may be arranged repeatedly in the first direction D1 and the second direction D2. In an embodiment, with respect to the first pixel PX1, the second pixel PX2 may be disposed on the side in the first direction DR1, and the third pixel PX3 may be disposed on the side in the second direction DR2, for example.

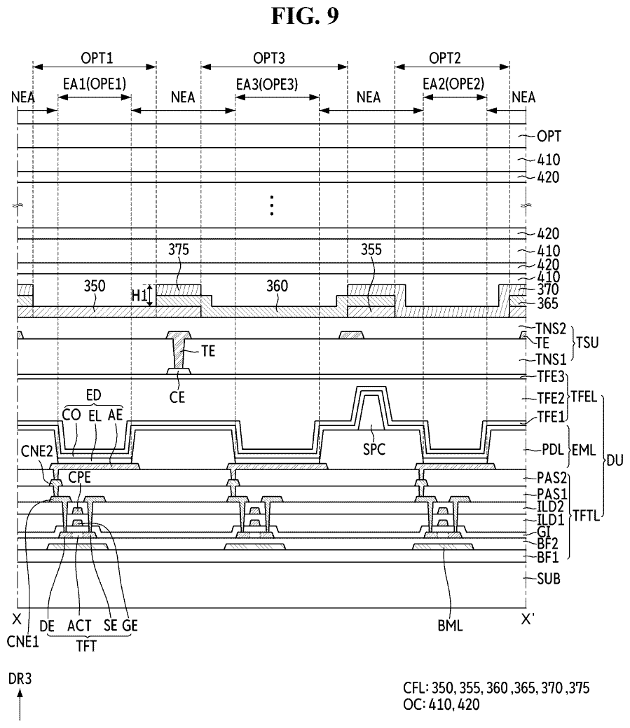

The emission areas EA1, EA2 and EA3 of the pixels PX1, PX2 and PX3 may include a first emission area EA1, a second emission area EA2 and a third emission area EA3 that emit lights of different colors. Each of the first to third emission areas EA1, EA2 and EA3 may emit red, blue or green light. The colors of lights emitted from the emission areas EA1, EA2 and EA3 may vary depending on the type of light-emitting elements ED (refer to FIG. 9) disposed in the light-emitting element layer EML to be described later. In an embodiment of the disclosure, the first emission area EA1 emits first light of red color, the second emission area EA2 emits second light of blue color, and the third emission area EA3 emits third light of green color. It is, however, to be understood that the disclosure is not limited thereto.

The first to third emission areas EA1, EA2 and EA3 may be defined by a plurality of openings OPE1, OPE2 and OPE3 defined in a pixel-defining layer PDL (refer to FIG. 9) of the light-emitting element layer EML, which will be described later. In an embodiment, the first emission area EA1 may be defined by the first opening OPE1 of the pixel-defining layer, the second emission area EA2 may be defined by the second opening OPE2 of the pixel-defining layer, and the third emission area EA3 may be defined by the third opening OPE3 of the pixel-defining layer, for example.

In an embodiment of the disclosure, the first to third emission areas EA1, EA2 and EA3 may have different areas or sizes. In the embodiment of FIG. 8, the first emission area EA1 may be larger than the second emission area EA2, and may be smaller than the third emission area EA3. The second emission area EA2 may be smaller than the third emission area EA3. The sizes of the emission areas EA1, EA2 and EA3 may vary depending on the sizes of the openings OPE1, OPE2 and OPE3 defined in the pixel-defining layer. The intensity of lights emitted from the emission areas EA1, EA2 and EA3 may vary depending on the size of the emission areas EA1, EA2 and EA3. The colors of the images displayed on the display device 10 or the electronic device 1 may be controlled by adjusting the size of the emission areas EA1, EA2 and EA3.

Although the emission areas EA1, EA2 and EA3 have different areas in the embodiment of FIG. 8, the disclosure is not limited thereto. The areas of the emission areas EA1, EA2 and EA3 may be equal to one another or may have different relative sizes. The areas of the emission areas EA1, EA2 and EA3 may be adjusted as desired according to the colors of the images desired by the display device 10 and the electronic device 1. In addition, the sizes of the emission areas EA1, EA2 and EA3 may be related to light efficiency, lifespan of the light-emitting elements ED, etc., and may have a trade-off relationship with reflection of external light. The sizes of the emission areas EA1, EA2 and EA3 may be adjusted by taking the above factors into account.

In addition, the plurality of openings OPE1, OPE2 and OPE3 and the plurality of output areas OPT1, OPT2 and OPT3 have a quadrangular shape, e.g., rectangular shape in the example shown in the drawings, the disclosure is not limited thereto. They may have a variety of shapes, such as an oval shape and a polygonal shape with rounded edges.

Each of the plurality of pixels PX1, PX2 and PX3 may include first to third emission areas EA1, EA2 and EA3 arranged next (adjacent) to each other, and may represent black-and-white or grayscale images. It should be understood, however, that the disclosure is not limited thereto. The combination of the emission areas EA1, EA2, and EA3 forming a single pixel group may be modified depending on the arrangement of the emission areas EA1, EA2 and EA3, and the colors of the lights emitted from them.

Referring back to FIG. 5, the color filter layer CFL may be disposed on the touch sensing layer TSU. The color filter layer CFL may be associated with each of the emission areas EA1, EA2 and EA3. The color filter layer CFL may transmit light of a color wavelength associated with each of the emission areas EA1, EA2 and EA3 and may absorb or block light of other wavelengths. In addition, the color filter layer CFL may prevent color mixing by absorbing or blocking light between the emission areas EA1, EA2 and EA3.

The overcoat layer OC may be disposed on the color filter layer CFL. The overcoat layer OC may provide a flat surface over the color filter layer CFL having different levels and may protect the color filter layer CFL. In an embodiment, the overcoat layer OC may include moisture absorbent to prevent the color filter layer CFL from being damaged by permeation of moisture. A more detailed description thereon will be given later.

An optical layer OPT may be disposed on the overcoat layer OC. The optical layer OPT is for improving the optical properties of the display device, and may include an anti-glare member or an anti-reflection member, for example. It should be understood, however, that the disclosure is not limited thereto. The optical layer OPT may also include an anti-fingerprint member, etc.

Hereinafter, the display device in the embodiment will be described in more detail with reference to other drawings.

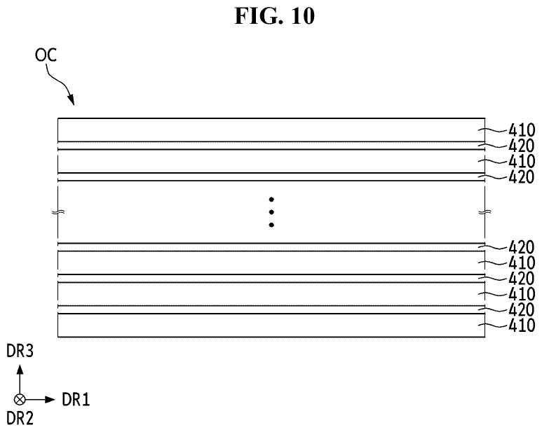

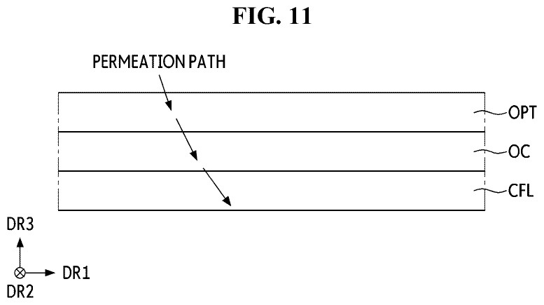

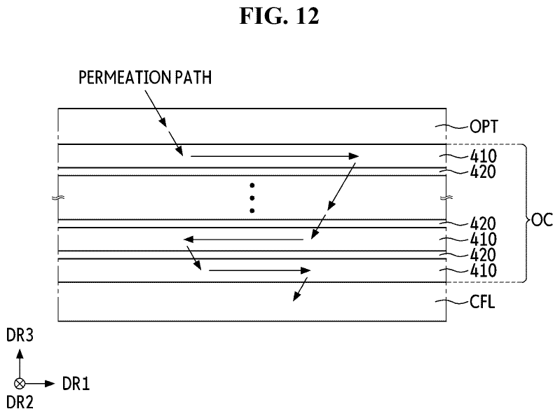

FIG. 9 is a cross-sectional view taken along line X-X′ of FIG. 8. FIG. 10 is an enlarged cross-sectional view of an embodiment of an overcoat layer of a display device according to the disclosure. FIG. 11 is a view schematically showing a path of moisture permeation in a single overcoat layer. FIG. 12 is a view schematically showing an embodiment of a path of moisture permeation in an overcoat layer according to the disclosure.

Referring to FIG. 9 in conjunction with FIG. 8, a display panel 100 of a display device 10 in an embodiment may include a display layer DU, a touch sensing layer TSU, a color filter layer CFL, an overcoat layer OC and an optical layer OPT. The display layer DU may include a substrate SUB, a thin-film transistor layer TFTL, a light-emitting element layer EML and an encapsulation layer TFEL.

The substrate SUB may be a base substrate or a base member. The substrate SUB may be a flexible substrate that may be bent, folded, or rolled. In an embodiment, the substrate SUB may include, but is not limited to, a polymer resin such as PI, for example. In another embodiment, the substrate SUB may include a glass material or a metal material.

The thin-film transistor layer TFTL may include a first buffer layer BF1, a bottom metal layer BML, a second buffer layer BF2, a thin-film transistor TFT, a gate insulator GI, a first inter-dielectric layer ILD1, a capacitor electrode CPE, a second inter-dielectric layer ILD2, a first connection electrode CNE1, a first passivation layer PAS1, a second connection electrode CNE2 and a second passivation layer PAS2.

The first buffer layer BF1 may be disposed on the substrate SUB. The first buffer layer BF1 may include an inorganic film capable of preventing permeation of air or moisture. In an embodiment, the first buffer layer BF1 may include a plurality of inorganic films stacked on one another alternately, for example.

The bottom metal layer BML may be disposed on the first buffer layer BF1. In an embodiment, the bottom metal layer BML may be made up of a single layer or multiple layers of one of molybdenum (Mo), aluminum (Al), chromium (Cr), gold (Au), titanium (Ti), nickel (Ni), neodymium (Nd), Tantalum (Ta) and copper (Cu) or any alloys thereof, for example.

The second buffer layer BF2 may cover the first buffer layer BF1 and the bottom metal layer BML. The second buffer layer BF2 may include an inorganic film capable of preventing permeation of air or moisture. In an embodiment, the second buffer layer BF2 may include a plurality of inorganic films stacked on one another alternately, for example.

The thin-film transistor TFT may be disposed on the second buffer layer BF2 and may form a pixel circuit of each of a plurality of pixels. In an embodiment, the thin-film transistor TFT may be a driving transistor or a switching transistor of the pixel circuit, for example. The thin-film transistor TFT may include a semiconductor layer ACT, a source electrode SE, a drain electrode DE and a gate electrode GE.

The semiconductor layer ACT may be disposed on the second buffer layer BF2. The semiconductor layer ACT may overlap the bottom metal layer BML and the gate electrode GE in the thickness direction and may be insulated from the gate electrode GE by the gate insulator GI. The material of a part of the semiconductor layer ACT may be made conductive to form the source electrode SE and the drain electrode DE.

The gate electrode GE may be disposed on the gate insulator GI. The gate electrode GE may overlap the semiconductor layer ACT with the gate insulating layer GI interposed therebetween.

The gate insulator GI may be disposed on the semiconductor layer ACT. In an embodiment, the gate insulator GI may cover the semiconductor layer ACT and the second buffer layer BF2, and may insulate the semiconductor layer ACT from the gate electrode GE, for example. The gate insulator GI may include a contact hole through which the first connection electrode CNE1 passes.

The first inter-dielectric layer ILD1 may cover the gate electrode GE and the gate insulator GI. The first inter-dielectric layer ILD1 may include a contact hole through which the first connection electrode CNE1 passes. The contact holes of the first inter-dielectric layer ILD1 may be connected to the contact holes of the gate insulator GI and the contact holes of the second inter-dielectric layer ILD2.

The capacitor electrode CPE may be disposed on the first inter-dielectric layer ILD1. The capacitor electrode CPE may overlap with the gate electrode GE in the thickness direction. The capacitor electrode CPE and the gate electrode GE may form a capacitance.

The second inter-dielectric layer ILD2 may cover the capacitor electrode CPE and the first inter-dielectric layer ILD1. The second inter-dielectric layer ILD2 may include a contact hole through which the first connection electrode CNE1 passes. The contact hole of the second inter-dielectric layer ILD2 may be connected to the contact hole of the first inter-dielectric layer ILD1 and the contact hole of the gate insulator GI.

The first connection electrode CNE1 may be disposed on the second inter-dielectric layer ILD2. The first connection electrode CNE1 may electrically connect the drain electrode DE of the thin-film transistor TFT with the second connection electrode CNE2. The first connection electrode CNE1 may be inserted into a contact hole defined in the second inter-dielectric layer ILD2, the first inter-dielectric layer ILD1, and the gate insulator GI to contact the drain electrode DE of the thin-film transistor TFT.

The first passivation layer PAS1 may cover the first connection electrode CNE1 and the second inter-dielectric layer ILD2. The first passivation layer PAS1 may protect the thin-film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 with a pixel electrode AE of the light-emitting element ED. The second connection electrode CNE2 may be inserted into a contact hole defined in the first passivation layer PAS1 to contact the first connection electrode CNE1.

The second passivation layer PAS2 may cover the second connection electrode CNE2 and the first passivation layer PAS1. The second passivation PAS2 may include a contact hole through which the pixel electrode AE of the light-emitting diode ED passes.

The light-emitting element layer EML may be disposed on the thin-film transistor layer TFTL. The light-emitting element layer EML may include a light-emitting element ED and a pixel-defining layer PDL. The light-emitting diode ED may include the pixel electrode (also referred to as an anode electrode) AE, an emissive layer EL, and a common electrode CO.

The pixel electrode AE may be disposed on the second passivation layer PAS2. The pixel electrode AE may be disposed in line with one of openings OPE1, OPE2 and OPE3 of the pixel-defining layer PDL. The pixel electrode AE may be electrically connected to the drain electrode DE of the thin-film transistor TFT through the first and second connection electrodes CNE1 and CNE2.

The emissive layer EL may be disposed on the pixel electrode AE. In an embodiment, the emissive layer EL may be, but is not limited to, an organic emissive layer including or consisting of an organic material, for example. When the emissive layer EL is an organic emissive layer, when the thin-film transistor applies a predetermined voltage to the pixel electrode AE of the light-emitting diode ED and the common electrode CO of the light-emitting diode ED receives a common voltage or cathode voltage, the holes and electrons may move to the emissive layer EL through the hole transporting layer and the electron transporting layer, respectively, and they combine in the emissive layer EL to emit light.

The common electrode CO may be disposed on the emissive layer EL. In an embodiment, the common electrode CO may be implemented as an electrode common to all pixels, instead of being disposed as a separated electrode for each of the pixels, for example. The common electrode CO may be disposed on the emissive layer EL in the first to third emission areas EA1, EA2 and EA3, and may be disposed on the pixel-defining layer PDL in remaining (the other) areas than the first to third emission areas EA1, EA2 and EA3.

The common electrode CO may receive a common voltage or a low-level voltage. When the pixel electrode AE receives the voltage equal to the data voltage and the common electrode CO receives the low-level voltage, a potential difference is formed between the pixel electrode AE and the common electrode CO, so that light may be emitted from the emissive layer EL.

The pixel-defining layer PDL may include a plurality of openings OPE1, OPE2 and OPE3, and may be disposed on the second passivation layer PAS2 and a part of the pixel electrode AE. The pixel-defining layer PDL may include the first opening OPE1, the second opening OPE2 and the third opening OPE3, and each of the openings OPE1, OPE2 and OPE3 is a part of the pixel electrode AE. As described above, the openings OPE1, OPE2 and OPE3 of the pixel-defining layer PDL may define the first to third emission areas EA1, EA2 and EA3, respectively, and a non-emission area NEA. The openings OPE1, OPE2 and OPE3 of the pixel-defining layer PDL may have different areas or sizes. The pixel-defining layer PDL may separate and insulate the pixel electrode AE of one of the plurality of light-emitting diodes ED from the pixel electrode of another one of the light-emitting diodes ED.

The pixel-defining layer PDL may include a light-absorbing material to prevent light reflection. In an embodiment, the pixel-defining layer PDL may include a polyimide (“PI”)-based binder, and pigments in which red, green and blue are mixed, for example. In an alternative embodiment, the pixel-defining layer PDL may include a cardo-based binder resin and a combination of lactam black pigment and blue pigment. In an alternative embodiment, the pixel-defining layer PDL may include carbon black.

A spacer SPC may be disposed on the pixel-defining layer PDL. The spacer SPC may prevent underlying layers from being damaged by the contact with a mask during a deposition process of the emissive layer EL. The spacer SPC may be disposed directly on the pixel-defining layer PDL and may be in line with the non-emission area NEA. The spacer SPC may include an organic material and may have a thickness of 1 μm or more.

The encapsulation layer TFEL may be disposed on the common electrode CO to cover the light-emitting diodes ED. The encapsulation layer TFEL may include at least one inorganic layer to prevent permeation of oxygen or moisture into the light-emitting element layer EML. The encapsulation layer TFEL may include at least one organic layer to protect the light-emitting element layer EML from foreign substances such as dust.

The encapsulation layer TFEL may include a first encapsulation layer TFE1, a second encapsulation layer TFE2 and a third encapsulation layer TFE3. The first encapsulation layer TFE1 and the third encapsulation layer TFE3 may be inorganic encapsulation layers, and the second encapsulation layer TFE2 disposed therebetween may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include an organic insulating material. Organic insulating materials may include an acrylic resin, an epoxy resin, polyimide, polyethylene, etc., for example. The second encapsulation layer TFE2 may be formed by curing a monomer or by applying a polymer.

The touch sensing layer TSU may be disposed on the encapsulation layer TFEL. The touch sensing layer TSU may include a first touch insulating layer TNS1, a second touch insulating layer TNS2, driving electrodes TE, and bridge electrodes CE. Although not shown in the drawings, the touch sensing layer TSU may further include the sensing electrodes RE shown in FIG. 7.

The bridge electrodes CE may be disposed on the third encapsulation layer TFE3. The bridge electrodes CE may be disposed in the non-emission area NEA. In an embodiment, the bridge electrodes CE may overlap with the non-emission area NEA, for example. The bridge electrodes CE may not overlap with the first to third emission areas EA1, EA2 and EA3.

The first touch insulating layer TNS1 may be disposed on the bridge electrode CE and the third encapsulation layer TFE3. The first touch insulating layer TNS1 may include an organic film or an inorganic film. In an embodiment, the first touch insulating layer TNS1 may include an organic film such as an acrylic resin, an epoxy resin, polyimide and polyethylene, or may include an inorganic film such as silicon nitride, silicon oxide and silicon nitride, for example.

The driving electrodes TE may be disposed directly on the first touch insulating layer TNS1. The driving electrodes TE may be disposed in the non-emission area EA. In an embodiment, the driving electrodes TE may overlap with the non-emission area EA, for example. The driving electrodes TE may not overlap with the first to third emission areas EA1, EA2 and EA3. The driving electrodes TE may be connected to the bridge electrodes CE through contact holes penetrating through the first touch insulating layer TNS1. Although not shown in the drawings, the driving electrodes TE and the sensing electrodes RE (refer to FIG. 7) may be disposed on the first touch insulating layer TNS1.

The driving electrodes TE may be made up of a single layer of molybdenum (Mo), titanium (Ti), copper (Cu), aluminum (Al), or indium tin oxide (“ITO”), or may be made up of a stack structure of aluminum and titanium (Ti/Al/Ti), a stack structure of aluminum and ITO (ITO/Al/ITO), an APC alloy an alloy of silver (Ag), palladium (Pd), and copper (Cu)) and a stack structure of an APC alloy and ITO (ITO/APC/ITO).

The second touch insulating layer TNS2 may be disposed on the driving electrodes TE and the first touch insulating layer TNS1. The second touch insulating layer TNS2 may cover the driving electrodes TE and the first touch insulating layer TNS1 to provide a flat surface over the underlying elements. The second touch insulating layer TNS2 may include one of the above-listed materials for the first touch insulating layer TNS1.

The color filter layer CFL may be disposed on the touch sensing layer TSU. The color filter layer CFL may include a first color filter 350, a second color filter 360, and a third color filter 370. In addition, it may include a first color pattern 355, a second color pattern 365, and a third color pattern 375.

The first color filter 350 may be disposed on the encapsulation layer TFEL and may overlap with the first emission area EA1. The first color pattern 355 may be spaced apart from the first color filter 350 and may be disposed in line with the non-emission area NEA. The first color filter 350 and the first color pattern 355 may be in direct contact with the encapsulation layer TFEL.

The first color filter 350 and the first color pattern 355 may selectively transmit the first light (e.g., red light) and may block or absorb the second light (e.g., blue light) and the third light (e.g., green light). According to the embodiment, the first color filter 350 may be a red color filter and may include a red colorant such as a red dye and a red pigment. As used herein, the colorant encompasses a dye as well as a pigment.

The second color filter 360 may be in line with the third emission area EA3. According to the embodiment, one side of the second color filter 360 may be disposed in the non-emission area NEA and overlap with the neighboring (adjacent) first color filter 350. The opposite side of the second color filter 360 may be disposed in the non-emission area NEA and overlap with the first color pattern 355. The second color pattern 365 may be spaced apart from the second color filter 360 and may be disposed in line with the non-emission area NEA. The second color pattern 365 may overlap with the first color filter 350 in the non-emission area NEA.

The second color filter 360 and the second color pattern 365 may selectively transmit the third light (e.g., green light) and may block or absorb the first light (e.g., red light) and the second light (e.g., blue light). In an embodiment, the second color filter 360 may be a green color filter and may include a green colorant such as a green dye and a green pigment, for example.

The third color filter 370 may be in line with the second emission area EA2. The third color pattern 375 may be spaced apart from the third color filter 370 and may be disposed in line with the non-emission area NEA. The third color pattern 375 may overlap with the first color filter 350 and the second color filter 360 in the non-emission area NEA.

The third color filter 370 may selectively transmit light of the second color (e.g., blue light) and may block and absorb light of the first color (e.g., red light) and light of the third color (e.g., green light). In an embodiment, the third color filter 370 may be a blue color filter and may include a blue colorant such as a blue dye and a blue pigment, for example.

The first to third color filters 350, 360 and 370 and the first to third color patterns 355, 365 and 375 overlap each other in the non-emission area NEA to block or absorb light. In an embodiment, in the non-emission area NEA disposed on one side of the third emission area EA3, the first color filter 350, the second color filter 360 and the third color pattern 375 overlap one another, for example. In the non-emission area NEA disposed on the opposite side of the second emission area EA2, the first color pattern 355, the second color filter 360 and the third color filter 370 may overlap one another.

The overcoat layer OC may be disposed on the color filter layer CFL. The overcoat layer OC may cover the color filter layer CFL to provide a flat surface over the underlying elements having different levels. In addition, the overcoat layer OC may protect the underlying stacked structure, e.g., the color filter layer CFL. In the color filter layer CFL, bubble defects or film delamination may be caused due to moisture permeating from the outside.

According to the embodiment, the overcoat layer OC may include a plurality of organic films 410 and a plurality of inorganic films 420. The overcoat layer OC may be formed in a structure in which a plurality of organic films 410 and a plurality of inorganic films 420 are alternately stacked on one another in the third direction DR3.

An organic film 410 may be disposed on the color filter layer CFL, and an inorganic film 420 may be disposed on the organic film 410, and so on. The organic film 410 disposed directly on the color filter layer CFL may provide a flat surface by filling the height difference between the portions where the color patterns 355, 365 and 375 are stacked and the portions where the color filters 350, 360 and 370 are disposed, for example. To this end, the organic film 410 (hereinafter referred to as the lowest organic film) disposed directly on the color filter layer CFL and in contact with the color filter layer CFL may have a degree of planarization (“DOP”) of 90% or more. In an embodiment, the DOP of the lowest organic film may range from 90% to 100%, for example. The DOP may be expressed by Equation 1 below:

$$DOP = [ 1 - ( Height Difference of Lowest Organic Film / Height Difference of Underlying Pattern ] * 100 \qquad [ Equation 1 ]$$

where the height difference of the underlying pattern refers to the vertical height difference H1 between the upper surface of the first color filter 350 in the first emission area EA1 and the upper surface of the third color pattern 375 near the first emission area EA1. The height difference of the lowest organic film refers to the value obtained by subtracting the vertical distance between the upper surface of the first color filter 350 and the upper surface of the lowest organic film from the sum of the height difference H1 of the underlying pattern and the vertical distance between the upper surface of the third color pattern 375 and the upper surface of the lowest organic film. In an embodiment, when the height difference of the lowest organic film is zero, the DOP of the lowest organic film may be 100%, for example.

The plurality of organic films 410 may have a thickness in the range of 1 micrometer (μm) to 20 μm. The thicknesses of the plurality of organic films 410 may be equal to one another, but the disclosure is not limited thereto. The organic films 410 may have different thicknesses. In an embodiment of the disclosure, the organic film 410 disposed directly on the color filter layer CFL may be thicker than other organic films 410 within the above range of thickness to provide flat surface over the color filter layer CFL.

The plurality of organic films 410 may include an organic material. The organic material may include an acrylic or epoxy monomer. In addition, the organic material may further include a photoinitiator, an additive, a solvent, etc., in addition to the above-described monomer. In an embodiment, the photoinitiator may include a radical initiator or an ionic initiator, and the additive may include a leveling agent, a sensitizer, etc., for example. The solvent may include ethylene glycol dimethyl ether (“EDM”) or propylene glycol methyl ether acetic acid (“PGMEA”), etc. In addition, the plurality of organic films 410 may further include inorganic particles to increase surface strength. The inorganic particles may include SiO₂, Al₂O₃, TiO₂, or zirconia, for example.

In an embodiment, the plurality of organic films 410 may include polysilsesquioxane (“PSSQ”) represented by the following chemical formula. Polysilsesquioxane has a strength similar to glass and accordingly may protect the underlying elements from external shock.

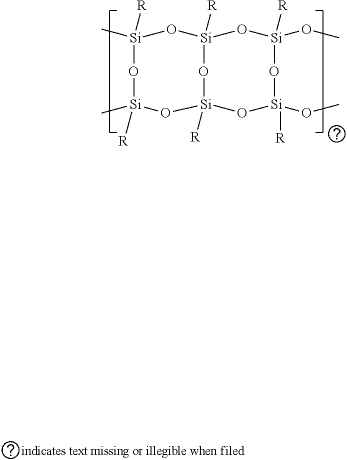

where R denotes

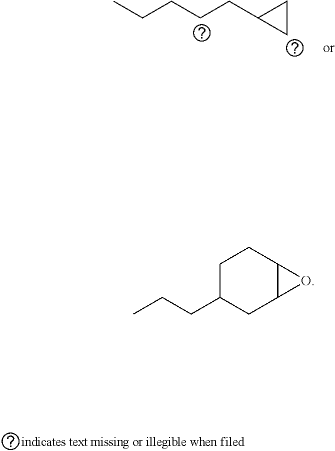

Among the plurality of organic films 410, the organic film 410 disposed at the uppermost position (hereinafter referred to as the highest organic film) may include a different material from a material of remaining (the other) organic films 410. The highest organic film 410 may be a layer forming the top of the overcoat layer OC. The highest organic film 410 may further include a wear-resistant material to give wear resistance (e.g., slip properties), and remaining (the other) organic films 410 except for the highest organic film 410 may include no wear-resistant material. The wear-resistant material may include one or more selected from silicone, polytetrafluoroethylene (“PTFE”), calcium carbonate, maleic acid, molybdenum, and magnesium stearate. The wear-resistant material may be physically mixed with or chemically bonded to the organic material. In an embodiment, silicone may be chemically bonded to the organic material in the form of functional groups, for example.

As described above, the lowest organic film 410 of the overcoat layer OC in the embodiment may provide a flat surface over the underlying elements having different heights, and the highest organic film 410 may give wear resistance to improve scratch resistance.

The inorganic films 420 may be interposed between the organic films 410. The inorganic films 420 may block or suppress permeation of moisture. The inorganic films 420 may include one of silicon nitride (SiNx), silicon oxide (SiOx), and silicon oxynitride (SiON).

Each of the inorganic films 420 may have a thickness of 10% or less of the thickness of one of the organic films 410. In an embodiment, each of the inorganic films 420 may have a thickness in the range of 0.1 μm to 2 μm, and preferably may have a thickness in the range of 0.1 μm to 1 μm, for example. When the thickness of the plurality of inorganic films 420 exceeds the above ranges, there may arise problems, e.g., in that stress may be applied to the inorganic films 420 and accordingly the interface may be delaminated or cracks may occur. Therefore, the thickness of the inorganic films 420 may lie within the above ranges.

The refractive index of the organic films 410 may be similar to that of the inorganic films 420. In an embodiment, the difference between the refractive index of the organic films 410 and the refractive index of the inorganic films 420 may be equal to or less than 0.05, for example. As long as the difference between the refractive index of the organic films 410 and the refractive index of the inorganic films 420 is equal to or less than 0.05, it is possible to prevent the transmittance from decreasing due to the reflection at the interfaces between the organic films 410 and the inorganic films 420.

As described above, the organic films 410 may be disposed at the bottom and top of the overcoat layer OC, respectively, and the inorganic films 420 may be arranged alternately with the organic films 410. The number of the organic films 410 may be greater than the number of the inorganic films 420. In an embodiment, the number of the organic films 410 may be one more than the number of the inorganic films (420), for example. Accordingly, as the organic films 410 are disposed at the bottom and top of the overcoat layer OC, respectively, it is possible to provide flatness at the bottom and wear resistance at the top.

An optical layer OPT may be disposed on the overcoat layer OC. The optical layer OPT may be bonded in the form of a film through an adhesive layer.

Referring to FIG. 11, when the overcoat layer OC is implemented as a single organic film layer, moisture may easily permeate from the outside into the color filter layer CFL through the optical layer OPT and the overcoat layer OC. When this happens, film delamination and bubble defects may occur in the color filter layer CFL.

In contrast, referring to FIG. 12, when the overcoat layer OC has a multilayer structure of organic films 410 and inorganic films 420, even when moisture permeates from the outside through the optical layer OPT, the path becomes longer in the overcoat layer OC, and thus the amount of moisture permeation may be significantly reduced. In this manner, it is possible to suppress film delamination and bubble defects in the color filter layer CFL.

Hereinafter, the results of reliability test and wear resistance test on single-layer and multi-layer overcoat layers will be described. In the display panel having the structure described above with reference to FIG. 9, a display panel with an overcoat layer made up of a single-layer organic film according to Comparative Example and a display panel with the overcoat layer according to the above-described embodiment (e.g., a multilayer structure of organic films and inorganic films) were fabricated.

The reliability test was performed by immersing the display panels thus fabricated in a water bath at 85° C. for 4 hours.

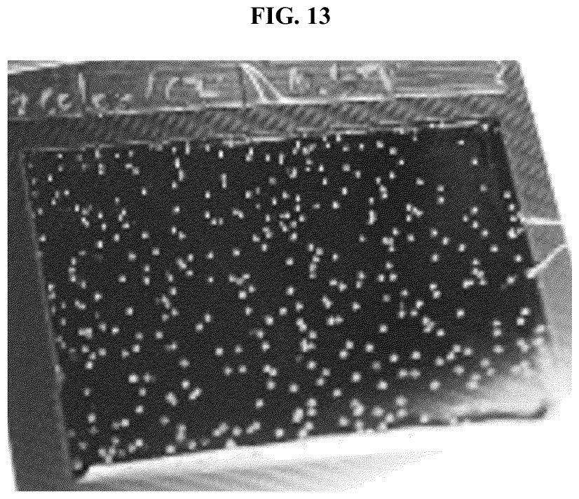

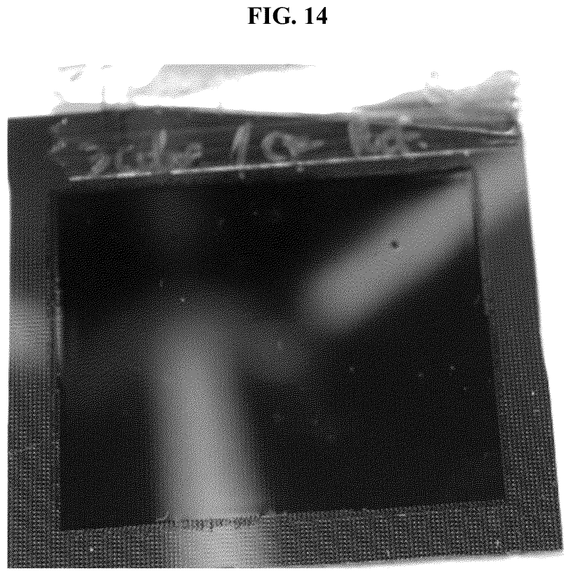

FIG. 13 is an image of the display panel according to Comparative Example after the reliability test. FIG. 14 is an image of the display panel in the embodiment after the reliability test.

Referring to FIG. 13, the display panel according to Comparative Example had bubble defects and film delamination on the surface. In contrast, referring to FIG. 14, the display panel in the embodiment did not have bubbles or film delamination on the surface.

It may be seen from the results that the display device in the embodiment may suppress bubble defects and film delamination by preventing the permeation of external moisture by forming the overcoat layer including multiple organic films and multiple inorganic films.

Incidentally, the wear resistance test was performed by fixing the fabricated display panels and repeatedly scratching them with a pencil multiple times.

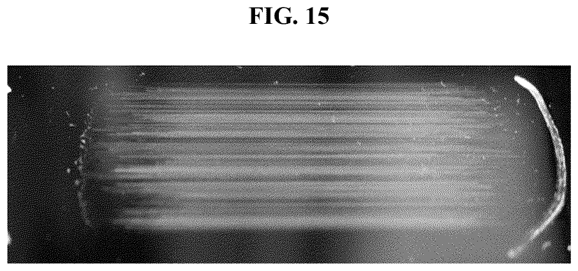

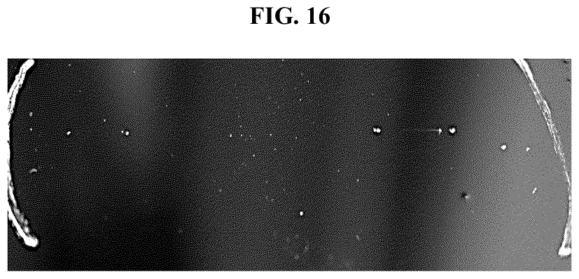

FIG. 15 is an image of the display panel according to Comparative Example after the wear resistance test. FIG. 16 is an image of an embodiment of the display panel after the wear resistance test.

Referring to FIG. 15, the display panel according to Comparative Example had numerous scratches on the surface. In contrast, referring to FIG. 16, the display panel in the embodiment had no scratch on the surface.

It may be seen from the results that the display device in the embodiment has excellent wear resistance by giving wear-resistant properties (e.g., including wear-resistant material) to the organic film at the top of the overcoat layer.

The display device in an embodiment of the disclosure may be applied to various electronic devices. The electronic device according to the an embodiment of the disclosure includes the display device described above, and may further include modules or devices having additional functions in addition to the display device.

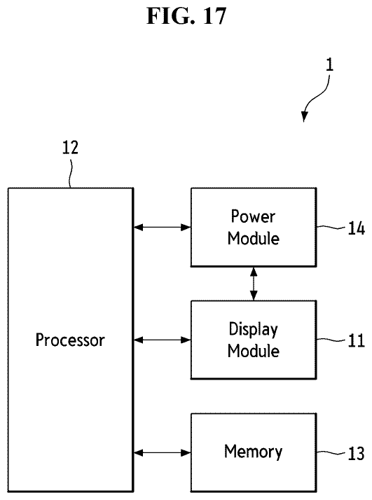

FIG. 17 is a block diagram of an embodiment of an electronic device according to the disclosure.

Referring to FIG. 17, the electronic device 1 in an embodiment of the disclosure may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as, for example a power adapter or a battery, and a power conversion module that converts the power supplied by the power supply module to generate power desired for the operation of the electronic device 1.

At least one of the components of the electronic device 1 according to the an embodiment of the disclosure may be included in the display device 10 in the embodiments of the disclosure. In addition, some modules of the individual modules functionally included in one module may be included in the display device 10, and other modules may be provided separately from the display device 10. In an embodiment, the display device 10 may include the display module 11, and the processor 12, the memory 13, and the power module 14 may be provided in the form of other devices within the electronic device 1 other than the display device 10, for example.

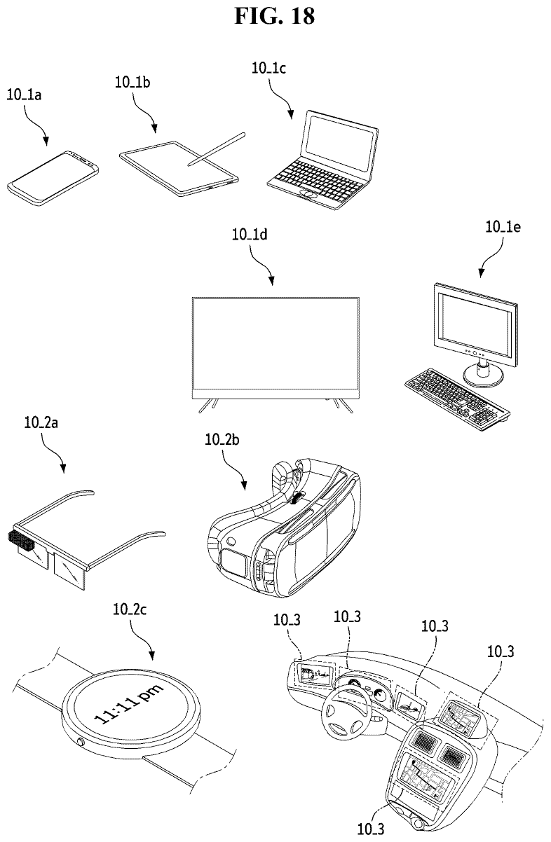

FIG. 18 is a schematic diagram of an electronic device according to various embodiments of the disclosure.

Referring to FIG. 18, various electronic devices to which display devices 10 in embodiments of the disclosure are applied may include not only image display electronic devices such as a smart phone 10_1a, a tablet PC 10_1b, a laptop 10_1c, a television (“TV”) 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a center information display (“CID”) and a room mirror display arranged on a dashboard, center fascia, and dashboard of an automobile.

In concluding the detailed description, those skilled in the art will appreciate that many variations and modifications may be made to the preferred embodiments without substantially departing from the principles of the disclosure. Therefore, the disclosed preferred embodiments of the disclosure are used in a generic and descriptive sense only and not for purposes of limitation.

What is claimed is:

1. A display device comprising:
a substrate;
a light-emitting element layer disposed on the substrate and emitting light;
an encapsulation layer disposed on the light-emitting element layer;
a touch sensing layer disposed on the encapsulation layer;
a color filter layer disposed on the touch sensing layer; and
an overcoat layer disposed on the color filter layer, the overcoat layer comprising:
organic films and inorganic films alternately stacked on one another, and
wherein the organic films are disposed at a bottom and a top of the overcoat layer, respectively.

2. The display device of claim 1, wherein the organic film disposed at the bottom of the overcoat layer among the organic films contacts the color filter layer.

3. The display device of claim 2, wherein the color filter layer comprises at least one color filter and at least one color pattern, and
wherein a degree of planarization of the organic film disposed at the bottom of the overcoat layer among the organic films is 90% or higher.

4. The display device of claim 1, wherein the organic film disposed at the top of the overcoat layer includes a different material from a material of remaining organic films.

5. The display device of claim 4, wherein the organic film disposed at the top of the overcoat layer among the organic films includes a wear-resistant material, and
wherein the remaining organic films among the organic films do not include the wear-resistant material.

6. The display device of claim 5, wherein the wear-resistant material comprises at least one selected from silicone, polytetrafluoroethylene, calcium carbonate, maleic acid, molybdenum, and magnesium stearate.

7. The display device of claim 1, wherein each of the inorganic films is disposed between the organic films, and comprises one of silicon nitride (SiNx), silicon oxide (SiOx), and silicon oxynitride (SiON).

8. The display device of claim 1, wherein each of the inorganic films has a thickness of 10% or less of a thickness of one of the organic films.

9. The display device of claim 1, wherein each of the organic films has a thickness of 1 micrometer to 20 micrometers.

10. The display device of claim 1, wherein a difference between a refractive index of the organic films and a refractive index of the inorganic films is equal to or less than 0.05.

11. The display device of claim 1, wherein the organic films include polysilsesquioxane.

12. A display device comprising:
a substrate;
a light-emitting element layer which is disposed on the substrate and emits light;
an encapsulation layer disposed on the light-emitting element layer;
a touch sensing layer disposed on the encapsulation layer;
a color filter layer disposed on the touch sensing layer; and
an overcoat layer disposed on the color filter layer, the overcoat layer comprises:
organic films and inorganic films alternately stacked on one another, and
wherein a number of the organic films is greater than a number of the inorganic films.

13. The display device of claim 12, wherein the organic film disposed at the top of the overcoat layer includes a different material from a material of remaining organic films.

14. The display device of claim 13, wherein the organic film disposed at the top of the overcoat layer among the organic films includes a wear-resistant material, and
wherein the remaining organic films among the organic films do not include the wear-resistant material.

15. The display device of claim 14, wherein the wear-resistant material comprises at least one selected from silicone, polytetrafluoroethylene, calcium carbonate, maleic acid, molybdenum, and magnesium stearate.

16. The display device of claim 12, wherein each of the inorganic films is disposed between the organic films, and comprises one of silicon nitride (SiNx), silicon oxide (SiOx), and silicon oxynitride (SiON).

17. The display device of claim 12, wherein each of the inorganic films has a thickness of 10% or less of a thickness of one of the organic films.

18. The display device of claim 12, wherein each of the organic films has a thickness of 1 micrometer to 20 micrometers.

19. The display device of claim 12, wherein a difference between a refractive index of the organic films and a refractive index of the inorganic films is equal to or less than 0.05.

20. An electronic device, comprising:
a display device configured to provide an image, the display device comprising:
a substrate;
a light-emitting element layer disposed on the substrate and emitting light;
an encapsulation layer disposed on the light-emitting element layer;
a touch sensing layer disposed on the encapsulation layer;
a color filter layer disposed on the touch sensing layer; and
an overcoat layer disposed on the color filter layer;
a processor configured to provide an image data signal to the display device;
a memory configured to store a data information for operation; and
a power module configured to generate power,
wherein the overcoat layer comprises organic films and inorganic films alternately stacked on one another, and
wherein the organic films are disposed at a bottom and a top of the overcoat layer, respectively.
